(19) United States
(12) Patent Application Publication
(10) Pub. No.: US 2005/0059271 A1
(43) Pub. Date: Mar. 17, 2005

(54) ELECTRICAL CONNECTOR HAVING IMPROVED CONTACTS

(76) Inventor: Chi Zhang, Kunsan (CN)

Correspondence Address: WEI TE CHUNG;FOXCONN INTERNATIONAL, INC., 1650 MEMOREX DRIVE, SANTA CLARA, CA, 95050, US

(21) Appl. No.: 10/940,303

(22) Filed: Sep. 13, 2004

(30) Foreign Application Priority Data
Sep. 11, 2003 (CN) 03278515.1

(51) Int. Cl. H01R 12/00; H05K 1/00

(52) U.S. Cl. 439/74

(57) ABSTRACT

An electrical connector (1) includes an insulative housing (2) and a number of contacts (3). The insulative housing defines a mating space (23), a number of passageways (220) communicating with the mating space and a number of recesses (221). Each recess communicates with a corresponding passageway and a projection (222) is formed between the recess and the corresponding passageway. The contacts are received in the passageways and each has a hook portion (34) clasping a corresponding projection for preventing the contact from moving into the mating space.

### BACKGROUND OF THE INVENTION

1. Field of the Invention

The present invention generally relates to an electrical connector, and particularly to a board-to-board connector for electrically connecting two separate printed circuit boards (PCBs).

2. Description of Related Art

A board-to-board electrical connector assembly generally comprises a plug and a receptacle connectors mounted on two separate PCBs, respectively, to electrically connect with the two PCBs. U.S. Pat. No. 6,379,161 (the '161 patent) discloses a receptacle connector. The receptacle connector of the '161 patent comprises an insulative housing and a plurality of contacts. The insulative housing defines a mating slot and a plurality of passageways at opposite sides of the mating slot and communicating with the mating slot. The passageways extend throughout a bottom wall of the insulative housing to thereby forming a corresponding number of through holes in the bottom wall. The contacts are received in the passageways with mating portions thereof exposed into the mating slot and with tail portions thereof retained in the through holes.

However dimensions of the through holes are usually little bigger than dimensions of the tail portions retained therein for facilitating inserting the contacts into the passageways. So retention of the tail portions of the contacts in the through holes is unreliable, the mating portions of the contacts are apt to move into the mating slot, thereby adversely affecting a mating between the receptacle connector and a complementary plug connector.

U.S. Pat. No. 5,639,248 discloses an electrical connector assembly including a male and a female connectors. The male connector has a housing and a plurality of male terminals. The male terminals are attached to opposite side walls of the housing with their first and second catches embedded in top ends and floors, respectively, of the opposite side walls by insert molding. However, it is laborious and costly to manufacture the male connector by insert molding.

Hence, an electrical connector having improved contacts is desired.

### SUMMARY OF THE INVENTION

An object of the present invention is to provide an electrical connector having improved contacts which can be reliably retained in an insulative housing thereof.

To achieve the above object, an electrical connector in accordance with the present invention comprises an insulative housing and a plurality of contacts. The insulative housing defines a mating space, a plurality of passageways communicating with the mating space and a plurality of recesses. Each recess communicates with a corresponding passageway and a projection is formed between the recess and the corresponding passageway. The contacts are received in the passageways and each has a hook portion clasping a corresponding projection for preventing the contact from moving into the mating space.

Other objects, advantages and novel features of the invention will become more apparent from the following detailed description when taken in conjunction with the accompanying drawings.

### BRIEF DESCRIPTION OF THE DRAWINGS

FIG. 1 is an exploded perspective view of an electrical connector in accordance with the present invention;

FIG. 2 is a cross-sectional view taken along line 2-2 of FIG. 1;

FIG. 3 is an assembled perspective view of the electrical connector of FIG. 1 before tail portions of contacts thereof are bent to their final configurations;

FIG. 4 is a cross-sectional view taken along line 4-4 of FIG. 3;

FIG. 5 is an assembled perspective view of the electrical connector of FIG. 1 after the tail portions of the contacts thereof have been bent to their final configurations; and

FIG. 6 is a cross-sectional view taken along line 6-6 of FIG. 5.

### DETAILED DESCRIPTION OF THE INVENTION

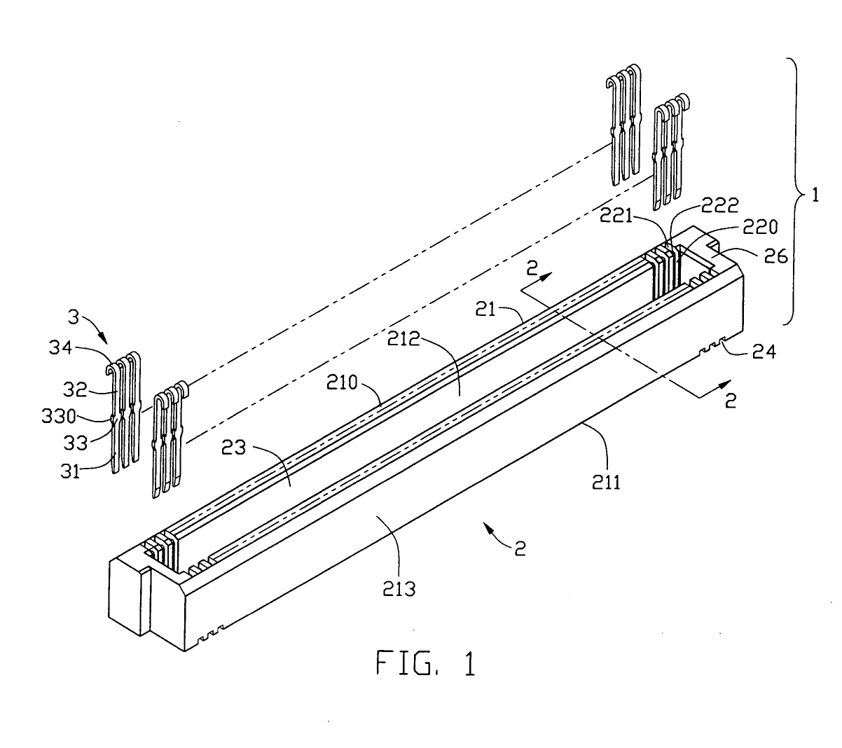

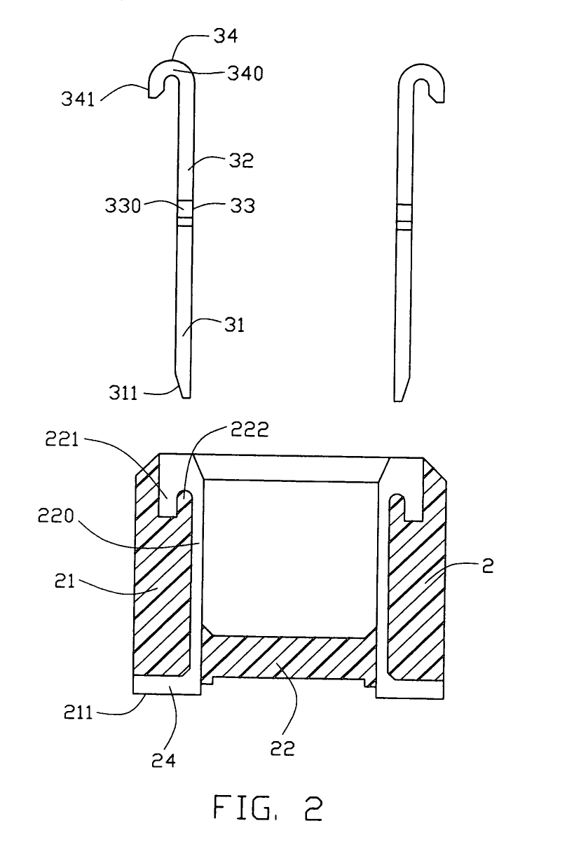

Referring to FIGS. 1 and 2, an electrical connector 1 in accordance with the present invention comprises an insulative housing 2 and a plurality of contacts 3.

The insulative housing 2 is elongated and comprises a pair of opposite sidewalls 21, a pair of opposite end walls 26 connecting with the sidewalls 21 and a bottom wall 22 connecting with lower ends of the sidewalls 21. A mating space 23 is formed between the sidewalls 21 and the end walls 26 for receiving a complementary connector (not shown). Each sidewall 21 has a mating face 210, a mounting face 211 opposite to the mating face 210, an inner face 212 confronting the mating space 23, and an outer face 213 opposite to the inner face 212. Each sidewall 21 defines a plurality of passageways 220 in the inner face 212, a plurality of recesses 221 in the mating face 210, and a plurality of grooves 24 in the mounting face 211. Each recess 221 laterally communicates with an upper end of a corresponding passageway 220 and a projection 222 is formed between the recess 221 and the corresponding passageway 220. The passageways 220 extend downwardly along the inner face 212 and penetrate through the bottom wall 22. Each groove 24 laterally communicates with a lower end of a corresponding passageway 220 and extends laterally throughout the mounting face 211.

Each contact 3 comprises a mating portion 32, a hook portion 34, a retention portion 33 extending downwardly from a lower end of the mating portion 32, and a tail portion 31 extending downwardly from the retention portion 33. The hook portion 34 comprises a curved portion 340 bent from an upper end of the mating portion 32 and a latch portion 341 extending downwardly from the curved portion 340. The retention portion 33 is formed with a pair of barbs 330 on opposite sides thereof. The tail portion 31 has a lead-in 311 on a free end thereof.

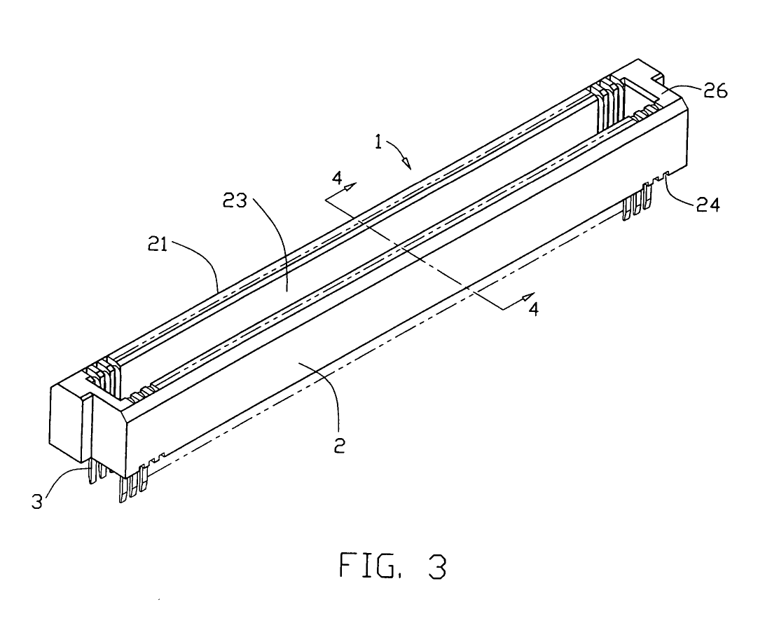

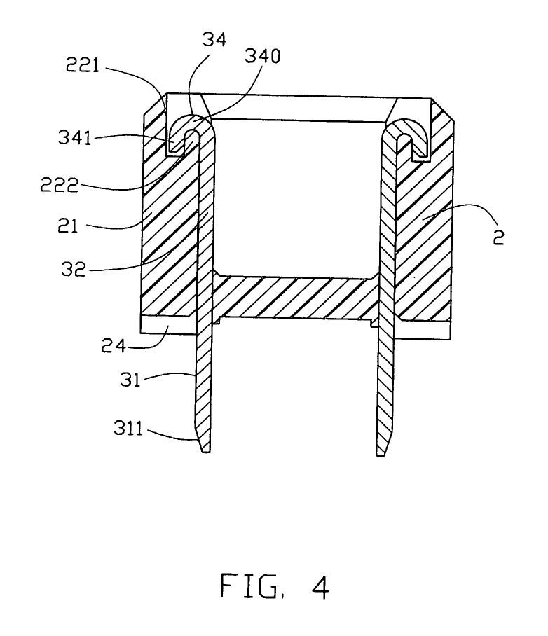

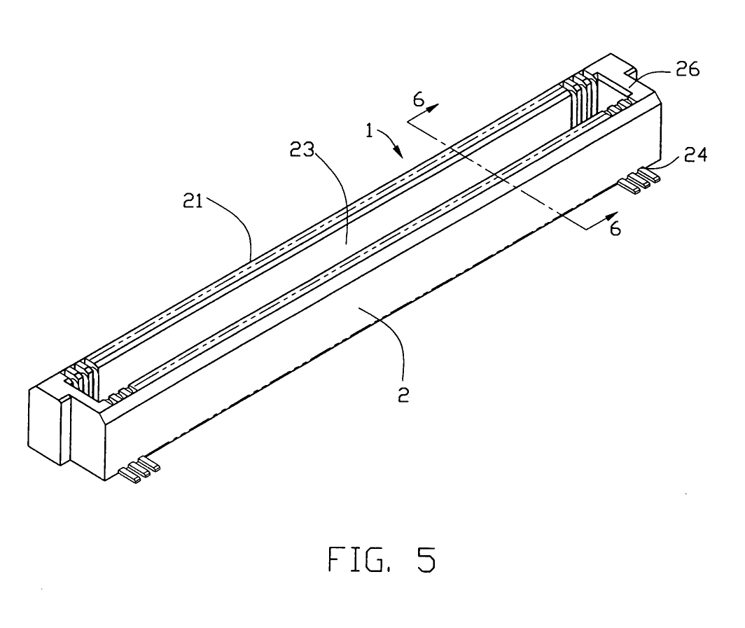

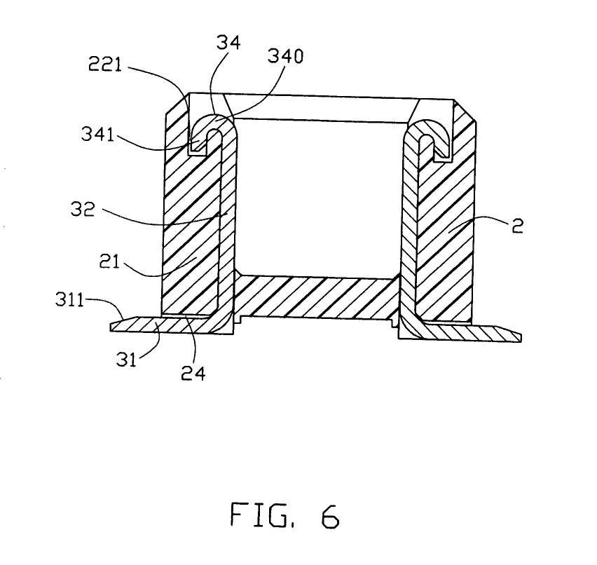

Referring to FIGS. 3-6, in assembly, the contacts 3 are inserted into the passageways 220 from the mating face 210 by guiding of the lead-ins 311 with the mating portion 32 exposed into the mating space 23 for connecting with contacts of the complementary connector. The barbs 330 engage with the sidewalls 21 for securing the contacts 3 in the passageways 220. The hook portions 34 clasp the projections 222 with the latch portions 341 received in the recesses 221 for ensuring the mating portions 32 snugly abutting against inner faces of the passageways 220. Then the tail portions 31 are laterally and outwardly bent and received in the grooves 24 with free ends thereof extending beyond the outer faces 213.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. An electrical connector comprising:
an insulative housing comprising two opposite sidewalls, two opposite end walls connecting with the two sidewalls, and a mating space formed between the sidewalls and the end walls, at least one of the sidewalls comprising a plurality of passageways communicating with the mating space, a plurality of recesses communicating with the passageways, and a plurality of projections each between one passageway and a corresponding recess; and
a plurality of contacts each comprising a mating portion received in a corresponding passageway of the insulative housing and exposed into the mating space, a retention portion extending downwardly from the mating portion, a tail portion extending from the retention portion, and a hook portion bent from the mating portion and clasping a corresponding projection; wherein
the hook portion comprises a curved portion and a latch portion extending downwardly from the curved portion and received in the recess; wherein
the retention portion of each contact is formed with a pair of barbs on opposite sides thereof to engage with the sidewall; wherein
each sidewall has a mating face, a mounting face opposite to the mating face, an inner face confronting the mating space, and an outer face opposite to the inner face, and wherein the recesses and the passageways are defined in the mating face and the inner face of the at least one sidewall, respectively; wherein
the at least one sidewall defines a plurality of grooves in the mounting face thereof and communicating with the passageways, and wherein the tail portions of the contacts laterally extend beyond the outer face of the at least one sidewall through the grooves.

2-7. (canceled)
